(19) United States
(12) Patent Application Publication
(10) Pub. No.: US 2026/0367149 A1
(43) Pub. Date: Nov. 19, 2026

(54) ON-CHIP FUNCTIONAL PATH MONITOR TO PRE-EMPTIVELY DETECT TIMING FAILURES ON FUNCTIONAL PATHS

(71) Applicant: NVIDIA Corporation, Santa Clara, CA (US)

(72) Inventors: Suhas Satheesh, Baulkham Hills (AU); Tezaswi Raja, San Jose, CA (US); Anoop Gopinath, Muncie, IN (US); Shalimar Rasheed, San Jose, CA (US); Charles Gamiz, Mountain View, CA (US); Supal Bhosale, Fremont, CA (US); Utham Vingnani, Castro Valley, CA (US)

(21) Appl. No.: 19/210,922

(22) Filed: May 16, 2025

(51) Int. Cl. G01R 31/3193

(52) U.S. Cl. CPC G01R 31/31937

(57) ABSTRACT

A flop critical path monitor (FCPM) cell is disclosed. In one embodiment, the FCPM cell is placed in a selected functional path of an IC. The FCPM cell comprises data trim circuitry, a shadow flop, and comparison circuitry. The data trim circuitry is configured to delay a data signal applied to both the data trim circuitry and a flop in the selected functional path (functional flop). The shadow flop is configured to receive the delayed data signal from the data trim circuitry and a clock signal also applied to the functional flop. The comparison circuitry is configured to generate an FCPM output signal by comparing an output signal received from the functional flop and an output signal received from the shadow flop, where the FCPM output signal indicates a potential timing failure in the selected functional path when the shadow flop incurs a setup timing violation.

### TECHNICAL FIELD

This application is directed, in general, to detecting and correcting data communication errors in an integrated circuit (IC) or “chip” and, more specifically, to monitoring functional paths on-chip to preemptively detect potential timing failures on the functional paths.

### BACKGROUND

In many cases it is hard to trace timing failures of integrated circuits (ICs) of products, e.g. servers, already placed with customers, e.g., in data center applications, back to a specific cause. The uncertainty of a sudden, unpredicted failure of an IC can be expensive and time consuming, e.g., in unexpected downtime in addition to the cost to determine and correct a failure. Techniques to detect timing failures of ICs exist today, e.g., scan coverage, but these techniques are reactionary and can only detect the failure after it has occurred and can only detect the failure at time 0, not failures that develop over time.

### SUMMARY OF THE DISCLOSURE

In one aspect, a flop critical path monitor (FCPM) cell is disclosed. In one embodiment, the FCPM cell is placed in a selected functional path of an integrated circuit (IC). In one embodiment, the FCPM cell comprises data trim circuitry, a shadow flop, and comparison circuitry. The data trim circuitry is configured to delay a data signal, where the data signal is applied to both the data trim circuitry and a flop in the selected functional path (functional flop). The shadow flop, similar to the functional flop, is configured to receive the delayed data signal from the data trim circuitry and to receive a clock signal also applied to the functional flop. The comparison circuitry is configured to generate an FCPM output signal by comparing an output signal received from the functional flop and an output signal received from the shadow flop, where the FCPM output signal indicates a potential timing failure with the data signal received by the functional flop in the selected functional path when the shadow flop incurs a setup timing violation.

In another aspect, a method of determining silent data corruption in a selected functional path of an IC is disclosed. In one embodiment, the method comprises applying a data signal to a flop in the selected functional path (functional flop) and data trim circuitry in a FCPM cell placed in the selected functional path and applying a clock signal to the functional flop and a shadow flop in the FCPM cell. The method further comprises, delaying the data signal applied using the data trim circuitry of the FCPM cell and applying the delayed data signal from the data trim circuitry to the shadow flop. The method further comprises comparing an output of the functional flop with an output from the shadow flop using comparison circuitry and indicating a potential timing failure in the selected functional path of the IC based on the comparison when the shadow flop incurs a setup timing violation. The method further comprises storing the indication of the potential timing failure in the selected functional path of the IC in a register of a post-processing block of the IC and modifying operation of the IC based on the indication.

In yet another aspect, a method of determining silent data corruption in a plurality of selected functional paths of an IC is disclosed. In one embodiment, the method comprises applying a data signal to a flop in each of the plurality of selected functional paths (functional flops) and corresponding data trim circuitry in a FCPM cell placed in each of the plurality of selected functional paths and applying a clock signal to each of the functional flops and corresponding shadow flops for each of the plurality of selected functional paths. The method further comprises choosing one of the plurality of selected functional paths, delaying the applied data signal of the chosen selected functional path by the data trim circuitry of the FCPM cell, and applying the delayed data signal to the corresponding shadow flop in the chosen selected functional path. The method further comprises comparing an output of the functional flop with an output of the shadow flop for the chosen selected functional path and indicating a potential timing failure in the chosen selected functional path of the IC based on the comparison when the shadow flop incurs a setup timing violation. The method further comprises storing the indication of the potential timing failure for each chosen selected functional path of the IC in a register of a post-processing circuitry block of the IC and modifying operation of the IC based on the indication.

In still yet another aspect, an IC is disclosed. In one embodiment, the IC comprises at least one processing unit; at least one logic block communicatively coupled to the at least one processing unit; at least one memory block communicatively coupled to the at least one processing unit and the at least one logic block; at least one functional path using a portion of at least one of the at least one processing unit, the at least one logic block, or the at least one memory block; and a FCPM cell placed in a selected one of the at least one functional path of the IC. In one embodiment, the FCPM cell comprises data trim circuitry, a shadow flop, and comparison circuitry. The data trim circuitry is configured to delay a data signal, where the data signal is applied to both the data trim circuitry and a flop in the selected functional path (functional flop). The shadow flop, similar to the functional flop, is configured to receive the delayed data signal from the data trim circuitry and to receive a clock signal also applied to the functional flop. The comparison circuitry is configured to generate an FCPM output signal by comparing an output signal received from the functional flop and an output signal received from the shadow flop, where the FCPM output signal indicates a potential timing failure with the data signal received by the functional flop in the selected functional path when the shadow flop incurs a setup timing violation.

In still yet another aspect, a data center is disclosed. In one embodiment, the data center comprises a plurality of servers, where the servers include a plurality of integrated circuits (ICs) affixed to printed circuit boards and/or substrates of the servers. In one embodiment, each of the ICs comprise at least one processing unit; at least one logic block communicatively coupled to the at least one processing unit; at least one memory block communicatively coupled to the at least one processing unit and at least one logic block; at least one functional path using a portion of at least one of the at least one processing unit, at least one logic block, and at least one memory block; and a FCPM cell placed in a selected one of the at least one functional path of the IC. In one embodiment, the FCPM cell comprises data trim circuitry, a shadow flop, and comparison circuitry. The data trim circuitry is configured to delay a data signal, where the data signal is applied to both the data trim circuitry and a flop in the selected functional path (functional flop). The shadow flop, similar to the functional flop, is configured to receive the delayed data signal from the data trim circuitry and to receive a clock signal also applied to the functional flop. The comparison circuitry is configured to generate an FCPM output signal by comparing an output signal received from the functional flop and an output signal received from the shadow flop, where the FCPM output signal indicates a potential timing failure with the data signal received by the functional flop in the selected functional path when the shadow flop incurs a timing setup violation.

In still yet another aspect, a library of circuit designs is disclosed. In one embodiment, the library of circuit designs comprise a design for a FCPM)cell placed in a selected functional path of an IC. In one embodiment, the FCPM cell comprises data trim circuitry, a shadow flop, and comparison circuitry. The data trim circuitry is configured to delay a data signal, where the data signal is applied to both the data trim circuitry and a flop in the selected functional path (functional flop). The shadow flop, similar to the functional flop, is configured to receive the delayed data signal from the data trim circuitry and to receive a clock signal also applied to the functional flop. The comparison circuitry is configured to generate an FCPM output signal by comparing an output signal received from the functional flop and an output signal received from the shadow flop, where the FCPM output signal indicates a potential timing failure with the data signal received by the functional flop in the selected functional path when the shadow flop incurs a setup timing violation.

### BRIEF DESCRIPTION OF THE DRAWINGS

Reference is now made to the following descriptions taken in conjunction with the accompanying drawings, in which:

FIG. 1 illustrates a block diagram of an example of an integrated circuit (IC) constructed according to the principles of the disclosure;

FIG. 2 illustrates an example of a block diagram of a flop critical path monitor (FCPM) cell associated with a single functional path in the IC according to principles of the disclosure;

FIG. 3 illustrates a timing diagram of an example of operation of a FCPM cell with a setup timing violation of a shadow flop according to principles of the disclosure;

FIG. 4 illustrates an example of a block diagram of a FCPM cell associated with multiple functional paths in the IC according to principles of the disclosure;

FIG. 5 illustrates an example of a block diagram of an IC with FCPM cells deployed in selected functional paths in the IC to detect potential timing failures in the selected functional paths according to principles of the disclosure; and

FIG. 6 illustrates a flow diagram of an example of a method of determining silent data corruption in a functional path of the IC carried out according to the principles of the disclosure.

### DETAILED DESCRIPTION OF THE DISCLOSURE

One result of the above-described timing failures of ICs can be what is termed silent data corruption. Silent data corruption can occur, e.g., between servers in the data center; between different ICs on a substrate (inter-chip) in, e.g., a server; or within a single IC (intra-chip) on a substrate in, e.g., a server. In many cases silent data corruption is a result of timing failures, e.g., setup timing violations, that happen within a same IC impacting data communication within the IC and thereby causing data corruption in the IC. In an IC with billions of transistors, e.g., transistors formed as flip-flops (or just “flops”), a single timing error can affect the entire IC and, in some cases, can affect other ICs affixed to a same substrate. By extension, the single timing error can also affect a server in which the substrate with multiple ICs is part of and, in the extreme, can affect an entire data center. The harm caused by a single timing error in a single IC in any substrate in any server of a data center can, thus, be very high. Thus, tracing timing failures in ICs can be beneficial to predict silent data corruption.

In addition to tracing timing failures in ICs to predict silent data corruption, tracing timing failures in ICs is also useful to debug the ICs. For example, ICs are designed to run at a specific frequency for a given voltage level applied to or in the ICs. It is not uncommon that after design of an IC, upon first fabrication of the IC, the IC does not perform as expected, e.g., the specific frequency the IC is expected to run at for a given voltage level is not achieved in the first fabricated ICs. In some embodiments this specific frequency is a maximum frequency (fₘₐₓ) at which the IC can operate.

Many existing techniques exist today to help debug ICs. For example, sensors are added to the design of the IC so that when the IC is fabricated, information from these sensors can be used to debug the IC. Examples of these sensors include process monitor sensors, noise monitor sensors, current sensors, critical path monitor sensors, etc. Information from these sensors is very helpful in detecting a root cause of, e.g., the above-described timing failures or errors. Further, in many cases these sensors are placed on replicas of functional paths (“replica paths”) in the IC rather than in the actual functional paths themselves so that the sensors themselves do not degrade performance of the actual functional paths. Replica paths can be made of, e.g., ring oscillators where signal propagation through the ring oscillator of the replica path can be determined and compared to an expected signal propagation generated from a model (e.g., typically a SPICE model) for the IC. Or noise (typically voltage noise) can be measured on the ring oscillators of the replica paths to determine the impact of noise on a replica path. However, information from sensors in these replica paths doesn't necessarily reflect exactly what is happening in the functional paths.

Furthermore, it is desired to be able to correlate expectations of IC performance from a model of the IC, e.g., a SPICE model, to actual IC performance to improve IC performance of future ICs using the same or similar process technology.

This disclosure provides circuitry and a method of operating the circuitry that provides on-chip monitoring of a functional path (not a replica path) to preemptively detect potential timing failures in the functional path. In general, the disclosed circuitry includes a flip-flop (“flop”) that is in an actual functional path on an IC (not in a replica path as discussed above). In some embodiments, this flop in the functional path is a capture flop. That is, the input to the capture flop is from what is termed a launch flop in the functional path. In large scale ICs, there can be billions of these flops in functional paths.

The disclosed circuitry and method adds an additional cell connected to an existing flop in a selected functional path termed a flop critical path monitor (FCPM) cell. The FCPM cell is designed to monitor the actual functional path. The FCPM cell includes a second flop, e.g., a “shadow flop.” The shadow flop shares a clock signal and data with the existing flop in the selected functional path, i.e., the data applied to the data input of the existing flop in the selected functional path is also applied to the FCPM cell and the clock signal applied to the existing flop in the selected functional path is also applied to the FCPM cell. It should be noted that the output from the existing flop in the selected functional path as well as the clock signal applied to both the existing flop in the selected functional path and the FCPM cell are applied to other circuitry in the same functional path or other functional paths of the IC.

The FCPM cell further includes programmable delay circuitry to slightly delay the data applied to the FPCM cell associated with the existing flop in the selected functional path. This allows the data to reach the data input of the shadow flop slightly later than the data reaches the data input of the existing flop in the selected functional path. The programmable delay circuitry of the FCPM cell can be thought of, in some embodiments, as a data trim. The amount of data trim is determined by trim select inputs input to the programmable data trim delay circuitry of the FCPM cell. That is, an amount of delay to be introduced to the data input of the shadow flop of the FCPM cell is determined by signals applied to the trim select inputs to the FCPM cell. For example, if there are n trim select inputs to the FCPM cell, there are 2ⁿ different delay times that can be introduced to the data input to the shadow flop of the FCPM cell. In an embodiment with two trim select inputs to the FCPM cell, there are four levels of delay that can be introduced to the data input to the shadow flop in the FCPM cell. In some embodiments, the signals applied to the trim select inputs to the FCPM cell each comes from registers external to the FCPM cell associated with each of the trim select inputs. In some embodiments, the amount of time delay generated by the trim select inputs to the FCPM cell varies over expected process, voltage, and temperature variations. In some embodiments, the amount of this time delay generated by the trim select inputs to the FCPM cell is on the order of about 50 picoseconds.

The FCPM further includes comparison circuitry configured to compare data from an output of the shadow flop (data at the input of the shadow flop slightly delayed by the trim circuitry) with actual data output from the selected existing flop in the functional path. The comparison circuitry can be a comparator, which in some embodiments can simply be an XOR gate. When the shadow flop incurs a setup timing violation, the delayed nature of the data arriving at the shadow flop results in the shadow flop failing to capture correct data. The flop in the functional path (functional flop) has no such delays on data arriving at its input, resulting in correct capture of data. As such, an output of the comparison circuitry proactively flags potential timing failures or issues before they manifest in a functional path while existing conventional techniques, e.g., scan test or replica sensors as discussed above, only can identify potential timing issues after they occur.

It is important to place the FCPM cell close to the existing flop in the selected functional path in order to reduce additional loads the FCPM cells add to the functional path (as well as additionally loading the clock signal used elsewhere in a specific functional path and/or other functional paths of the IC). Since the FCPM cells, in addition to loading functional paths on the IC, also take additional space in each functional path they are applied to in the IC (albeit very little space since the circuitry in FCPM cell is very, very small, e.g., in some embodiments the FCPM is approximately only 5-6 times the size of a baseline flop), care is taken to determine how many FCPMs are added to functional paths to avoid consuming too much space on the IC. As with other design considerations, there is a tradeoff between how much silent data corruption detection is to be provided with the disclosed FCPMs and how much space and loading is required for the FCPMs to detect the silent data corruption. In some embodiments, the number of shadow flops of FCPM cells used in some ICs is about 0.1% of the total number of flops used in the IC. Moreover, tradeoffs can be made as to which blocks of an IC, e.g., SRAM, critical logic paths, etc., the FCPMs are placed in (e.g., in functional paths thereof) to give maximum insight into what is happening on the IC. Typically, the FCPMs are placed where potential timing failures may occur.

In some embodiments, the FCPM cell can monitor more than one functional path. In these embodiments, data input into flops of, e.g., two different functional paths are input to a single FCPM cell as is the data output from the flops of the two different functional paths. In these embodiments, the FCPM cell further includes a pair of multiplexers (MUXs) where data input to each of the flops in the two different functional paths are input to one of the pair of MUXs of the FCPM cell and data output from each of the flops of the two different functional paths are input into another of the pair of MUXs of the FCPM cell. The FCPM cell of this embodiment has an additional input to select which of the two functional paths is to be used by the single shadow flop of the FCPM cell.

Of course, the number of functional paths to be monitored by the FCPM cell could be further scaled. For example, if eight functional paths are to be monitored, the two MUXs would have eight inputs (for both the input to the flop in each of the eight functional paths being monitored and the output of the flop in each of the eight functional paths being monitored) and there would be three inputs to select which of the eight functional paths is to be used by the single shadow flop of the FCPM cell. In general, to monitor 2ⁿ number of functional paths, n inputs are needed to select which of the 2ⁿ functional paths is to be used by the single shadow flop of the FCPM cell. In these embodiments, the FCPM cell includes the data trim circuitry and comparator as disclosed above.

In some embodiments, output from the FCPM indicating silent data corruption can be stored in a register on the IC to document whether potential timing failures exist and to what extent the potential timing failures exist. This is particularly helpful when trying to determine fₘₐₓ, debug the IC, or correlate actual IC performance to an expected modeled performance of the IC as disclosed above. In some embodiments, the register is included in a post-processing block of the IC where, e.g., the contents of the register are used, e.g., in determining fₘₐₓ, debugging the IC, or correlating actual IC performance to an expected modeled performance of the IC.

In other embodiments, output from the FCPM can be used in live monitoring of the functional paths. This is particularly helpful in determining silent data corruption as disclosed above in real time at all times the IC is operating. In this case, live monitoring of the functional paths provides live feedback that can be used to take specific actions to correct the silent data corruption. In some embodiments, the live feedback is stored in the register of the post-processing block of the IC. Here, when the live feedback indicates potential timing failures above a threshold indicated by not only FCPMs but also other sensors, e.g., the process monitor sensors, noise monitor sensors, current sensors, critical path monitor sensors, etc. disclosed above can be interrogated to provide additional information that can be used to enable a decision to correct the silent data corruption indicated by the FCPM cells. In some embodiments, based on the live feedback from the FCPM cells (and, in some cases, input from other sensors on-chip in replica paths), it can be determined that circuitry local to an FCPM cell (or local to multiple FCPM cells) is faulty. In other embodiments, based on the live feedback from the FCPM cells (and, in some cases, input from other sensors on-chip in replica paths), it can be determined that various parameters are outside of nominal values, e.g., the live feedback (from the FPCM cells and, e.g., a noise monitor) may indicate that voltage noise is above expected or nominal values.

The data collected during live monitoring and live feedback helps better understand what is happening on the chip and, when timing failures are determined to be occurring, what could be causing the issues. Further, in some embodiments, if the live feedback from the FCPM cells (and is some cases in conjunction with inputs from other sensors in replica paths) indicates potential timing failures in a given functional path (or given functional paths), feedback could be sent back to clocking circuits for the specific functional path(s) to alter the clock signal, e.g., fₘₐₓ, for that functional path(s), e.g., slowing the clock signal, so that the potential timing failure is obviated (as determined from subsequent live feedback from the FPCM cells). Moreover, in embodiments where the potential timing failures are parameter based, e.g., voltage noise greater than a threshold, when the live feedback from the FCPM cells indicates the potential timing failures no longer exist, the clocking circuits could alter the clock signal for that function path(s) back to its original value, e.g., speeding the clock back up to its original value.

Another application of the information from the FCPM cells could be used in data center scheduling algorithms. For example, where the FCPM data shows a high or medium risk for potential timing failures in a specific node of the data center (e.g., specific functional paths on ICs in the data center application), the data center scheduling algorithm could not schedule routines that require high levels of quality of service, e.g., like long run deep learning training algorithms. And where the FCPM data shows a low risk for potential timing failures in a specific node of the data center, the data center scheduling algorithm would schedule these higher quality of service routines.

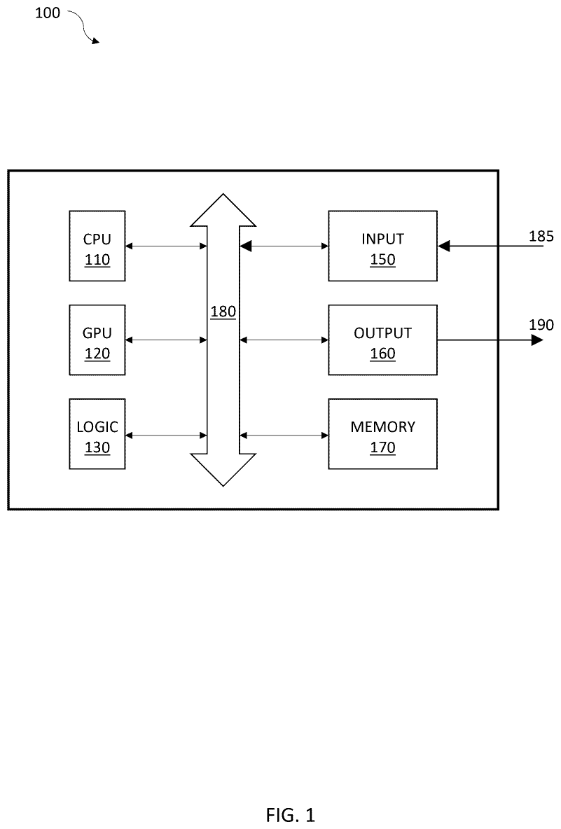

Referring to the drawings, specifically FIG. 1, a block diagram of an integrated circuit (IC) 100 constructed according to the principles of the disclosure is shown. IC 100 includes at least one CPU 110, at least one GPU 120, optionally at least one logic block 130, input circuitry 150, output circuitry 160, and memory 170. Of course, in some embodiments IC 100 can include more than one CPU 110, GPU 120, or logic block 130 or, in other embodiments, IC 100 could omit any of CPU 110, GPU 120, or logic block 130. As depicted in FIG. 1, in some embodiments, CPU 110, GPU 120, logic block 130, input circuitry 150, output circuitry 160, and memory 170 communicate with each other over bus 180. In some embodiments, additional busses between different processing units (e.g., CPU 110, GPU 120, and logic block 130) and between different processing units (e.g., CPU 110, GPU 120, and logic block 130), input circuitry 150, output circuitry 160, and memory 170 can be employed (not shown). Memory 170 can be comprised of differing types of volatile memories (e.g., dynamic random access (DRAM) memory, SRAM memory, etc.) and/or non-volatile memories (e.g., read-only memory (ROM), erasable programmable read-only memory (EPROM), electrically erasable programmable read-only memory (EEPROM), flash memory, etc.). In some embodiments of IC 100, memory 170 includes on-chip SRAM which includes a writability monitoring circuit constructed in accordance with the principles of the disclosure as described below. Also as depicted in FIG. 1, IC 100's input circuitry 150 accepts signals 190 externally provided to IC 100 and IC 100's output circuitry 160 provides signals 195 external to IC 100.

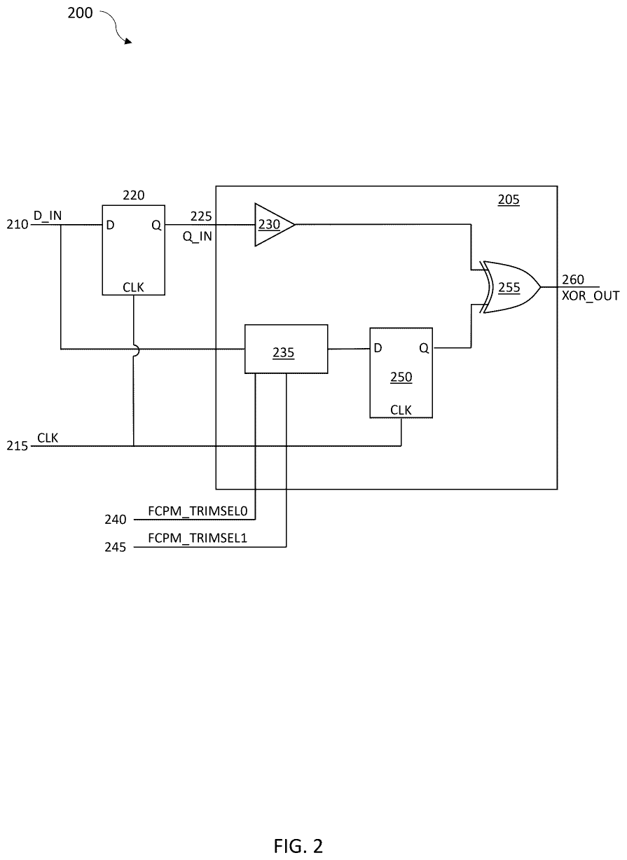

FIG. 2 illustrates an example of a block diagram 200 of a flop critical path monitor (FCPM) cell 205 associated with a selected single functional path in the IC according to principles of the disclosure. Signal 210, e.g., D_IN, is data from a selected actual functional path of the IC. Signal 210 is applied to both functional flop 220 (e.g., at the D input of functional flop 220) and programmable data trim circuitry 235 of FCPM cell 205. Clock signal 215, e.g., CLK, is applied to functional flop 220 and clocks functional flop 220. Output signal 225 is output from functional flop 220 (e.g., from the Q output of functional flop 220) as clocked by clock signal 215 and input, e.g., as input signal Q_IN, to associated FCPM cell 205.

FCPM cell 205 comprises, in some embodiments, isolation buffer 230, programmable trim circuitry 235, shadow flop 250, and a comparison circuit, e.g., comparator 255 (in some embodiments, comparator 255 is, as depicted in FIG. 2, an XOR gate). Programmable trim circuitry 235 delays signal 210 by an amount based on trim select signals 240/245 input to programmable data trim circuitry 235 as disclosed above. Trim select signals 240/245, e.g., FCPM_TRIMSEL0 and FCPM_TRIMSEL1, program the delay for programmable data trim circuitry 235. Trim select signals 240/245 are generated in another portion of the IC and applied to FCPM cell 205.

An output from programmable data trim circuitry 235 is applied to shadow flop 250 of FCPM cell 205 (e.g., the D input of shadow flop 250). Clock signal 215 clocks shadow flop 250 of FCPM cell 205 (in addition to clocking functional flop 220). An output from shadow flop 250, e.g., from the Q output of shadow flop 250, is input to a second input of comparator 255. Input signal 225 is applied to isolation buffer 230 of FCPM cell 205. An output from isolation buffer 230 is applied to a first input of a comparator 255. An output from comparator 255, e.g., signal XOR_OUT 260, is output from FCPM cell 205. Isolation buffer 230's main purpose is to provide predictable timing at the input of FCPM cell 205. In static timing analysis (STA), this ensures that the timing seen external to FCPM cell 205 doesn't vary depending on a state of the second input of comparator 255. The delay of isolation buffer 230 is intentionally made small so as not to affect the output from FCPM cell 205, e.g., output signal XOR_OUT 260, being correctly captured by downstream logic that aggregates data from, inter alia, FCPM cell 205 as described below.

In operation, FCPM cell 205 detects potential timing failures in a selected functional path. When there is a setup timing violation for shadow flop 250, e.g., setup time (tₛᵤ) violation for shadow flop 250, shadow flop 250 will not output a signal to comparator 255. Since there will be a logic high signal applied to comparator 255 (e.g., from the output Q of functional flop 220 as Q_IN signal 225 from signal 210) but there will not be a logic high signal from shadow flop 220, the output of comparator 255 will be high, indicating a potential timing failure of the selected functional path. This assumes that functional flop 220 does not have a setup timing violation itself. That is, the functional flop, e.g., functional flop 220 correctly captures data from signal 210.

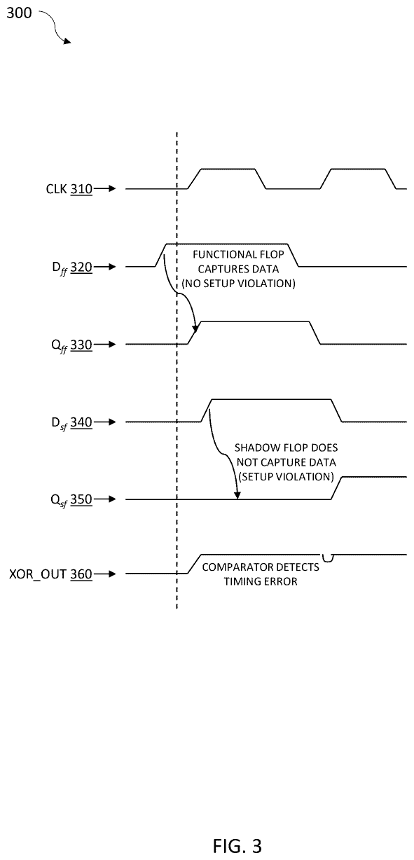

FIG. 3 illustrates timing diagram 300 of an example for the above-described operation of FCPM cell 205 as depicted in FIG. 2 with a setup timing violation of shadow flop 250 according to principles of the disclosure. Timing diagram 300 includes waveforms that demonstrate a timing sequence of operation of an FCPM, e.g., FCPM 205 of FIG. 2, to detect a potential timing failure in a functional path in an IC. Timing diagram 300 includes clock signal (CLK) 310 waveform (similar to the clock signal disclosed above), waveform 320 for an input to a functional flop (D_{ff}, similar to signal 210 input into functional flop 220 of FIG. 2), waveform 330 for an output from a functional flop (Q_{ff}, similar to Q_IN signal 225 of FIG. 2 and also similar to a signal input to a first input of comparator 255 of FIG. 2), waveform 340 for an input to a shadow flop (D_{sf}, similar to the signal output from programmable data trim circuitry 235 and input to shadow flop 250 of FIG. 2), waveform 350 for an output of a shadow flop (Q_{sf}, similar to the signal output from shadow flop 250 and input to a second input of comparator 255 of FIG. 2), and waveform 360 for a signal output from a comparator (XOR_OUT signal 260 output from comparator 255 of FIG. 2).

Once signal D_{ff} is asserted high as shown in waveform 320 (similar to signal 210 of FIG. 2 going high representing a data high for data on a functional path of an IC), Q_{ff} goes high as shown in waveform 330 (after a propagation delay for the functional flop, e.g., functional flop 220 of FIG. 2). This assumes, as discussed above, that the functional flop successfully captures the data high signal, e.g., signal 210 of FIG. 2 with no setup timing violation. As shown in waveform 340, signal D_{sf} (e.g., signal input to shadow flop 250 from programmable data trim circuitry 235 of FIG. 2) is asserted high after the delay introduced to signal D_{ff} (e.g., by programmable data trim circuitry 235 of FIG. 2). When there is a setup timing violation for the shadow flop, e.g., setup time (tₛᵤ) violation (e.g., for shadow flop 250 of FIG. 2), the signal output from the shadow flop (e.g., shadow flop 250 of FIG. 2) does not go high as shown in signal Q_{sf} of waveform 350. As a result of this setup timing violation of the shadow flop, the output of the comparator (e.g., XOR gate 255 of FIG. 2) remains high, as shown in waveform 360, because the signal applied to the first input of the comparator is high and the signal applied to the second input of the comparator is low. This indicates a potential timing failure in the functional path.

However, when there is no setup timing violation for the shadow flop, the signal output from the shadow flop will go high as a result of the input to the shadow flop. Thus, waveform 350 showing the output of the shadow flop, e.g., signal Q_{sf}, would go high after signal D_{sf} of waveform 340 goes high (after a propagation delay of the shadow flop). At this point, both inputs to the comparator (e.g., XOR gate 255 of FIG. 2) would transition low since both of its inputs are high. Here, the output of the comparator (e.g., signal XOR_OUT of waveform 360 of FIG. 3 and signal 260 of FIG. 2) will go low (thus, no indication of a potential timing failure in this selected functional path will be made).

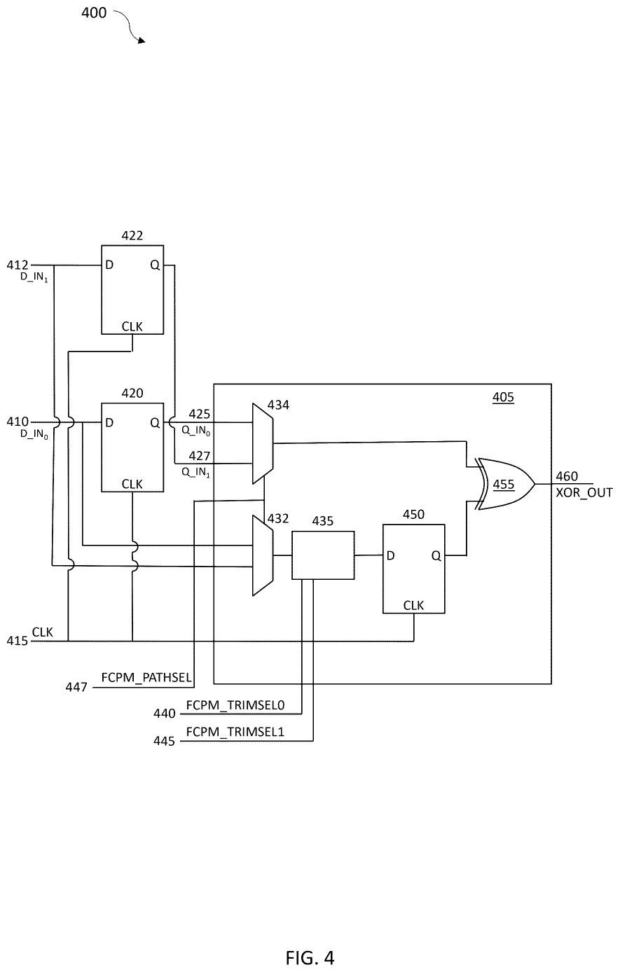

FIG. 4 illustrates an example of a block diagram 400 of a flop critical path monitor (FCPM) cell 405 associated with multiple, e.g., two, selected functional paths in the IC according to principles of the disclosure. Signal 410, e.g., D_IN₀, is data from a first selected actual functional path of the IC. Signal 412, e.g., D_IN₁, is data from a second, separate, selected actual functional path of the IC. Signal 410 is applied to both first functional flop 420 (e.g., at the D input of first functional flop 420) and a first input of first multiplexer (MUX) 432 of FCPM cell 405. Signal 412 is applied to both second functional flop 422 (e.g., at the D input of second functional flop 422) and a second input of first MUX 432 of FCPM cell 405. Clock signal 415, e.g., CLK, is applied to both first functional flop 420 and second functional flop 422. Output signal 425 is output from first functional flop 420 (e.g., from the Q output of first functional flop 420) as clocked by clock signal 415 and input, e.g., as input signal Q_IN₀ to a first input of second MUX 434. Output signal 427 is output from second functional flop 422 (e.g., from the Q output of second functional flop 422) as clocked by clock signal 415 and input, e.g., as input signal Q_IN₁ to a second input of second MUX 434.

FCPM cell 405 comprises, in some embodiments, first MUX 432, second MUX 434, programmable data trim circuitry 435, shadow flop 450, and a comparison circuit, e.g., comparator 455 (in some embodiments, comparator 455 is, as depicted in FIG. 4, an XOR gate). Signal 447, e.g., FCPM_PATHSEL, is applied select line inputs for both first MUX 432 and second MUX 434 and causes first MUX 432 to select between signal 410 (e.g., D_IN₀) and signal 412 (e.g., D_IN₁) and causes second MUX 434 to select between signal 425 (e.g., Q_IN₀) and signal 427 (e.g., Q_IN₁). As with programmable data trim circuitry 235 of FIG. 2, programmable data trim circuitry 435 delays either signal 410 or 412 (as selected by signal 447 applied to the select line input of first MUX 432) by an amount based on trim select signal input 440/445 input to programmable data trim circuitry 435 as disclosed above. Trim select signals 440/445, e.g., FCPM_TRIMSEL0 and FCPM_TRIMSEL1, program the delay for programmable data trim circuitry 435. As with FCPM cell 205 of FIG. 2, trim select signals 440/445 are generated in another portion of the IC and applied to FCPM cell 405. Moreover, signal 447, e.g., FCPM_PATHSEL, is also generated in another portion of the IC (either the same portion of the IC that generates trim select signal 440/445 or a different portion of the IC) and applied to FCPM 405.

Similar to FCPM cell 205 of FIG. 2, an output from programmable data trim circuitry 435 is applied to shadow flop 450 of FCPM cell 405 (e.g., the D input of shadow flop 450). Clock signal 415 also clocks shadow flop 450 of FCPM cell 405 (in addition to clocking first functional flop 410 and second functional flop 412). The output from shadow flop 450 (e.g., from the Q output of shadow flop 450) is applied to a second input of comparator 455. Signal 447 is used, as described above, to select which functional path is to be used by comparator 455 of FCPM cell 405 by second MUX 434, e.g., selecting the signal output from the first functional path's functional flop 420 (e.g., Q_IN₀) or the second functional path's functional flop 422 (e.g., Q_IN₁). The output from second MUX 434 is applied to the first input of comparator 455. An output from comparator 455, e.g., signal XOR_OUT 460, is output from FCPM cell 455.

In operation, as with FCPM cell 205 disclosed above, FCPM cell 405 detects potential timing failures in one of the selected functional paths, e.g., the functional path whose data is input, e.g., D_IN₀, to first functional flop 420 or the functional path whose data is input, e.g., D_IN₁, to second functional flop 422. As with the setup timing violations described above with regard to shadow flop 250 of FIG. 2, the set timing violation here are also setup time (tₛᵤ) violations for shadow flop 450. As with FIG. 2, if there is a setup timing violation of shadow flop 450, output signal 460, e.g., XOR_OUT, will be high, indicating a potential timing failure in the selected functional path, and if there is no setup timing violation of shadow flop 450, output signal 460, e.g., XOR_OUT, will be low, indicating no potential timing failure in the selected functional path.

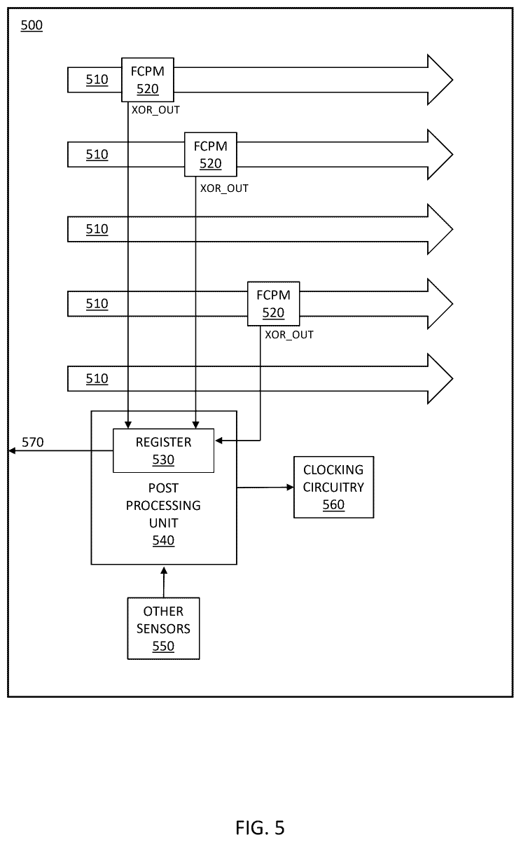

FIG. 5 illustrates an example of a block diagram of an IC 500 with FCPM cells deployed in selected functional paths in the IC 500 to detect potential timing failures in the selected functional paths according to principles of the disclosure. FIG. 5 depicts an example IC 500 with a plurality of functional paths that are each denoted by element number 510 and collectively referred to as functional paths 510. While FIG. 5 depicts IC 500 with the five functional paths 510, the IC 500 can include any number of functional paths. As depicted in FIG. 5, three of the five functional paths 510 are selected to be monitored for potential timing failures (although the number of selected functional paths to be monitored could by any number of functional paths), e.g., the first, second and fourth functional paths 510 with FCPMs 520. FCPMs 520 are similar to FCPM 205 of FIG. 2 and/or FCPM 405 of FIG. 4.

As disclosed above, output signals from FCPMs 520, e.g., XOR_OUT signals, are generated by their respective FCPM 520. These output signals are input into register 530 of post-processing unit 540 of the IC 500. When any of the output signals are high, e.g., XOR_OUT, is high for any of the FCPMs 520, these signals will be stored in register 530. Also input into post-processing unit 540 are signals from other sensors 550. These other sensors are similar to the process monitor sensors, noise monitor sensors, current sensors, critical path monitor sensors, etc. described above. Post-processing unit 540 considers inputs from register 530 (containing information regarding potential timing failures in the actual functional paths) and these other sensors to debug the IC, correlate expectations of performance of the IC, and/or alter operation of the IC.

For example, post-processing unit 540 can, based on the inputs from the potential timing failures in the functional paths stored in register 530 and/or inputs from the other sensors, determine that specific frequency, e.g., fₘₐₓ, can not be achieved. In this case, post-processing circuitry 540 will send control signals to clocking circuitry 560 to adjust an operating frequency for either the entire IC 500 or the portion of the IC 500 that a corresponding FCPM cell indicates as having a number of potential timing failures greater than a threshold. In some embodiments, clocking circuitry 560 controls clocking signals such as disclosed above, e.g., clock signal 215 (CLK) of FIG. 2 and/or clock signal 415 (CLK) of FIG. 4. The adjustment can be to slow the operating clock frequency down and then, if subsequent monitoring indicates a reduction in the number of potential timing failures, the adjustment can be to speed the operating clock frequency back up. In some embodiments, the portions of the IC 500 can be, e.g., blocks of logic; memories, e.g., SRAMs; or processing pipelines.

Post-processing unit 540 can alter the operation of the IC 500 in other ways, not just by altering an operating frequency. For example, if an FCPM 520 specific to a location of a processing pipeline indicates an above-threshold number of potential timing failures for that processing pipeline, post-processing unit 540 can send control signals to disable that particular processing pipeline and post-processing unit 540 can subsequently monitor the FCPM 520 for the particular processing pipeline and, if the number of potential timing failures from the FCPM 520 for the particular processing pipeline drops below the threshold, post-processing unit 540 can send control signals to enable the particular processing pipeline. Additionally, the determination of potential timing failures by post-processing unit 540 can also be used in a data center scheduling algorithm altering scheduling of specific data center operations based on the determined setup timing violations.

As discussed above, post-processing unit 540 considers inputs from register 530 (containing information regarding setup timing violations in the actual functional paths) and these other sensors to debug the IC 500 and/or correlate expectations of performance of the IC 500 (based on, e.g., SPICE simulations for the IC 500). In this case, post-processing unit 540 outputs this information to be used in debugging the IC 500 and/or correlation information via output line 570.

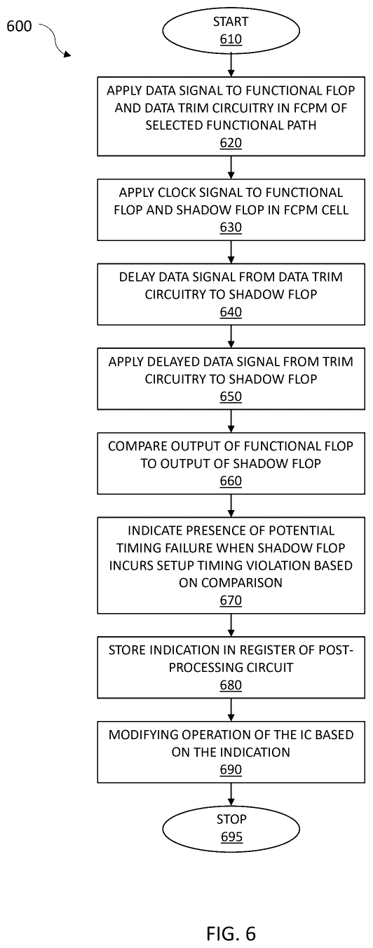

FIG. 6 illustrates a flow diagram 600 of an example of a method of determining silent data corruption in a functional path of an IC, such as IC 500, carried out according to the principles of the disclosure. In step 610, the method starts. At step 620, a data signal for a selected functional path (or, as disclosed above, multiple functional paths) is applied to a functional flop in the selected functional path and data trim circuitry in an FCPM of the selected functional path. As step 630, a clock signal is applied to both the functional flop in the selected functional path and a shadow flop in the FCPM. At step 640, the data signal is delayed using programmable data trim circuitry. At step 650, the delayed signal is applied to the shadow flop. At step 660, outputs from the functional flop and shadow flop are compared. At step 670, a presence of a potential timing failure is indicated based on the comparison. At step 680, the indication of the potential timing failure is stored in a register of a post-processing circuit. At step 690, operation of the IC is modified based on the stored indication. The method stops at step 695.

In some embodiments, a library of circuit designs includes the above-described FCPM cell. The library of circuit designs that includes the above-described FCPM cell is used by IC designers to design an IC that advantageously take advantage of the FCPM cell to detect and correct data communication errors that can occur in the IC.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

What is claimed is:

1. A flop critical path monitor (FCPM) cell placed in a selected functional path of an integrated circuit (IC), the FCPM cell comprising:
data trim circuitry configured to delay a data signal, wherein the data signal is applied to both the data trim circuitry and a flop in the selected functional path (functional flop);
a shadow flop, similar to the functional flop, configured to receive the delayed data signal from the data trim circuitry and to receive a clock signal also applied to the functional flop; and
comparison circuitry configured to generate an FCPM output signal by comparing an output signal received from the functional flop and an output signal received from the shadow flop, wherein the FCPM output signal indicates a potential timing failure in the selected functional path when the shadow flop incurs a setup timing violation.

2. The FCPM cell as recited in claim 1, wherein the potential timing failure is indicative of silent data corruption.

3. The FCPM cell as recited in claim 1, wherein the delay introduced to the data signal applied to the data trim circuitry is selected by at least one trim select input signal received by the data trim circuitry.

4. The FCPM cell as recited in claim 1, wherein the comparison circuitry is an XOR gate.

5. The FCPM cell as recited in claim 1, further comprising an isolation buffer configured to receive the output signal from the functional flop and output an isolated signal to the comparison circuitry.

6. The FCPM cell as recited in claim 1, further comprising a first and second multiplexer (MUX).

7. The FCPM cell as recited in claim 6, wherein:
a first input of the first multiplexer receives the data signal applied to the functional flop of the selected functional path and other inputs of the first multiplexer receive data signals applied to functional flops of each of other selected functional paths of the IC; and
a first input of the second multiplexer receives the output signal from the functional flop in the selected functional path and other inputs of the second multiplexer receive output signals from functional flops of each of the other selected functional paths of the IC.

8. The FCPM cell as recited in claim 7, wherein one of the selected functional path or other selected functional paths is chosen by the first and second multiplexers using at least one path select input signal externally applied to the FCPM cell and received by each of the first and second multiplexers.

9. The FCPM cell as recited in claim 8, wherein:
the data trim circuitry delays a data signal from the functional path chosen by the at least one path select input signal to the second multiplexer and outputs the delayed selected data signal to the shadow flop;
the comparison circuitry compares the output signal from functional flop of the functional path chosen by the at least one path select input signal to the signal output from the shadow flop.

10. The FCPM cell as recited in claim 9, wherein the signal output from the comparison circuitry indicates the a potential timing failure in the data signal in the functional path chosen by the at least one path select input signal when the shadow flop incurs a setup timing violation.

11. A method of determining silent data corruption in a selected functional path of an integrated circuit (IC), the method comprising:
applying a data signal to a flop in the selected functional path (functional flop) and data trim circuitry in a flop critical path monitor (FCPM) cell placed in the selected functional path;
applying a clock signal to the functional flop and a shadow flop in the FCPM cell;
delaying the data signal applied using data trim circuitry of the FCPM cell;
applying the delayed data signal from the data trim circuitry to the shadow flop;
comparing an output of the functional flop with an output of the shadow flop using comparison circuitry;
indicating a potential timing failure in the selected functional path of the IC when the shadow flop incurs a setup timing violation based on the comparison;
storing the indication of the potential timing failure in the selected functional path of the IC in a register of a post-processing circuitry block of the IC; and
modifying operation of the IC based on the indication.

12. The method as recited in claim 11, wherein the potential timing failure is indicative of silent data corruption.

13. The method as recited in claim 11, further comprising considering inputs from other sensors on the IC in the post-processing circuitry block of the IC when modifying operation of the IC.

14. The method as recited in claim 13, wherein the other sensors are selected from the group comprising process monitor sensors, noise monitor sensors, current sensors, and critical path monitor sensors.

15. The method as recited in claim 11, further comprising externally applying at least one trim select input to the FCPM to select the delay of the data signal.

16. The method as recited in claim 11, further comprising isolating the output of the functional flop before comparing the output of the functional flop with the output of the shadow flop.

17. The method as recited in claim 11, further comprising providing the indication stored in the register of the IC externally from the IC, wherein the indication is used by the IC in determining fₘₐₓ of the IC, debugging the IC, or correlating actual IC performance to an expected modeled performance of the IC.

18. The method as recited in claim 11, wherein the selected functional path is one of a plurality of selected functional paths of the IC and the method further comprises choosing the selected functional path from the plurality of selected functional paths.

19. A method of determining silent data corruption in a plurality of selected functional paths of an integrated circuit (IC), the method comprising:
applying a data signal to a flop in each of the plurality of selected functional paths (functional flops) and corresponding data trim circuitry in a flop critical path monitor (FCPM) cell placed in each of the plurality of selected functional paths;
applying a clock signal to each of the functional flops and corresponding shadow flops for each of the plurality of selected functional paths;
choosing one of the plurality of selected functional paths;
delaying the applied data signal of the chosen selected functional path using the data trim circuitry of the FCPM cell;
applying the delayed data signal to the corresponding shadow flop in the chosen selected functional path;
comparing an output of the functional flop with an output of the shadow flop for the chosen selected functional path;
indicating a potential timing failure in the chosen selected functional path of the IC when the shadow flop incurs a setup timing violation based on the comparison;
storing the indication of the potential timing failure for each chosen selected functional path of the IC in a register of a post-processing circuitry block of the IC; and
modifying operation of the IC based on the indication.

20. The method as recited in claim 19, wherein the potential timing failure is indicative of silent data corruption.

21. The method as recited in claim 19, wherein the choosing of the one of the plurality of selected functional paths is performed using at least one path select input signal applied to the FCPM of the chosen selected functional path.

22. The method as recited in claim 19, further comprising providing the indication in any of the chosen selected functional paths of the IC externally from the IC, wherein the indication is used by the IC in determining fₘₐₓ of the IC, debugging the IC, or correlating actual IC performance to an expected modeled performance of the IC.

23. An integrated circuit (IC), comprising:
at least one processing unit;
at least one logic block communicatively coupled to the at least one processing unit;
at least one memory block communicatively coupled to the at least one processing unit and the at least one logic block;
at least one functional path using a portion of at least one of the at least one processing unit, the at least one logic block, or the at least one memory block; and
a flop critical path monitor (FCPM) cell placed in a selected one of the at least one functional path of the IC, the FCPM cell comprising:
data trim circuitry configured to delay a data signal, wherein the data signal is applied to both the data trim circuitry and a flop in the selected functional path (functional flop);
a shadow flop similar to the functional flop configured to receive the delayed data signal from the data trim circuitry and to receive a clock signal also applied to the functional flop; and
comparison circuitry configured to generate an FCPM output signal by comparing an output signal received from the functional flop and an output signal from the shadow flop; wherein the FCPM output signal indicates a potential timing failure with the data signal received by the functional flop applied in the selected functional path when the shadow flop incurs a setup timing violation.

24. A data center, the data center comprising:
a plurality of servers, wherein the servers include a plurality of integrated circuits (ICs) affixed to printed circuit boards and/or substrates of the servers, each of the ICs comprising:
at least one processing unit;
at least one logic block communicatively coupled to the at least one processing unit;
at least one memory block communicatively coupled to the at least one processing unit and at least one logic block;
at least one functional path using a portion of at least one of the at least one processing unit, at least one logic block, and at least one memory block; and
a flop critical path monitor (FCPM) cell placed in a selected one of the at least one functional path of the IC, the FCPM cell comprising:
data trim circuitry configured to delay a data signal, wherein the data signal is applied to both the data trim circuitry and a flop in the selected functional path (functional flop);
a shadow flop, similar to the functional flop, configured to receive the delayed data signal from the data trim circuitry and to receive a clock signal also applied to the functional flop; and
comparison circuitry configured to generate an FCPM output signal by comparing an output signal received from the functional flop and an output signal received from the shadow flop, wherein the FCPM output signal indicates a potential timing failure with the data signal received by the functional flop in the selected functional path when the shadow flop incurs a setup timing violation.

25. A library of circuit designs, comprising:
a design for a flop critical path monitor (FCPM) cell placed in a selected functional path of an integrated circuit (IC), the FCPM cell comprising:
data trim circuitry configured to delay a data signal, wherein the data signal is applied to both the data trim circuitry and a flop in the selected functional path (functional flop);
a shadow flop, similar to the functional flop, configured to receive the delayed data signal from the data trim circuitry and to receive a clock signal also applied to the functional flop; and
comparison circuitry configured to generate an FCPM output signal by comparing an output signal received from the functional flop and an output signal received from the shadow flop, wherein the FCPM output signal indicates a potential timing failure with the data signal received by the functional flop in the selected functional path when the shadow flop incurs a setup timing violation.
